(19) United States
(12) Patent Application Publication
(10) Pub. No.: US 2006/0071258 A1
(43) Pub. Date: Apr. 6, 2006

(54) Semiconductor device

(76) Inventors: Kazuhiro Tomioka, Yokohama-shi (JP); Tomoaki Ishida, Yokohama-shi (JP); Masatoshi Fukushima, Yokohama-shi (JP); Masanobu Baba, Yokohama-shi (JP); Hiroyuki Kanaya, Yokohama-shi (JP); Haoren Zhuang, Hopewell Junction, NY (US)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/961,079

(22) Filed: Oct. 12, 2004

(30) Foreign Application Priority Data
Sep. 24, 2004 (JP) 2004-278030

(51) Int. Cl. H01L 29/94

(52) U.S. Cl. 257/296

(57) ABSTRACT

Disclosed is a semiconductor device comprising a semiconductor substrate, a capacitor provided above the semiconductor substrate and including a bottom electrode, a dielectric film provided on the bottom electrode, and a top electrode provided on the dielectric film, a mask film provided on the top electrode and used as a mask when a pattern of the capacitor is formed, wherein an inclination of a side surface of the mask film is gentler than an inclination of a side surface of the top electrode and an inclination of a side surface of the dielectric film.

### BACKGROUND OF THE INVENTION

1. Field of the Invention

The present invention relates to a semiconductor device having a capacitor.

2. Description of the Related Art

In recent years, development of ferroelectric memories using a ferroelectric film as dielectric film of a capacitor, that is, ferroelectric random access memories (FeRAM) have been pursued.

To achieve scale down in ferroelectric memories, it is important to reduce a distance between adjacent capacitors as well as an area occupied by a capacitor. Therefore, it is necessary to steepen side surfaces of a capacitor, that is, to increase the inclination angle (taper angle) thereof.

However, a good step coverage cannot be obtained with a large inclination angle, and thus it is difficult to securely cover a capacitor with an interlayer insulating film. This causes a problem of decrease in the film thickness of an interlayer insulating film formed on side surfaces of a capacitor, and a problem of generation of void on side surfaces of a capacitor. It also generates a void between adjacent capacitors.

As is clear from the above, inclination of side surfaces of a capacitor is important to obtain excellent ferroelectric memories. In conventional art, inclination of side surfaces of a capacitor is not optimized. Specifically, if the inclination of side surfaces of a capacitor is made gentle, that is, if the inclination angle thereof is reduced, the area occupied by a capacitor and a distance between adjacent capacitors are increased, and scale down becomes difficult. Conversely, if the inclination of the side surfaces of capacitors is steepened, that is, if the inclination angle thereof is increased, the step coverage thereof deteriorates, and it is difficult to securely cover a capacitor with an interlayer insulating film.

As prior art, Jpn. Pat. Appln. KOKAI Pub. No. 9-162311 (corresponding U.S. Pat. No. 6,097,051) proposes reducing the inclination angle of side surfaces of a capacitor to 750 or less. However, this reduces the inclination angle, and thus scale down of the ferroelectric memory cannot be achieved.

As described above, in the conventional art, inclination of side surfaces of a capacitor is not optimized. Therefore, it is difficult to achieve both scale down and good step coverage, and to obtain a semiconductor device having excellent property and reliability.

### BRIEF SUMMARY OF THE INVENTION

According to a first aspect of the present invention, there is provided a semiconductor device comprising: a semiconductor substrate; a capacitor provided above the semiconductor substrate and including a bottom electrode, a dielectric film provided on the bottom electrode, and a top electrode provided on the dielectric film; a mask film provided on the top electrode and used as a mask when a pattern of the capacitor is formed; wherein an inclination of a side surface of the mask film is gentler than an inclination of a side surface of the top electrode and an inclination of a side surface of the dielectric film.

According to a second aspect of the present invention, there is provided a semiconductor device comprising: a semiconductor substrate; a capacitor provided above the semiconductor substrate and including a bottom electrode, a dielectric film provided on the bottom electrode, and a top electrode provided on the dielectric film; a mask film provided on the top electrode and used as a mask when a pattern of the capacitor is formed; wherein an inclination of a side surface of the mask film and an inclination of a side surface of the top electrode are gentler than an inclination of a side surface of the dielectric film.

According to a third aspect of the present invention, there is provided a semiconductor device comprising: a semiconductor substrate; and a capacitor provided above the semiconductor substrate and including a bottom electrode, a dielectric film provided on the bottom electrode, and a top electrode provided on the dielectric film; wherein an inclination of a side surface of the top electrode is gentler than an inclination of a side surface of the dielectric film.

### BRIEF DESCRIPTION OF THE SEVERAL VIEWS OF THE DRAWING

FIGS. 1 to 4 are schematic cross-sectional views illustrating steps of manufacturing a semiconductor device according to a first embodiment of the present invention.

FIG. 5 is a schematic cross-sectional view illustrating a structure of a semiconductor device according to a second embodiment of the present invention.

FIG. 6 is a schematic cross-sectional view illustrating a structure of a semiconductor device according to a third embodiment of the present invention.

### DETAILED DESCRIPTION OF THE INVENTION

Embodiments of the present invention are described below with reference to drawings.

### Embodiment 1

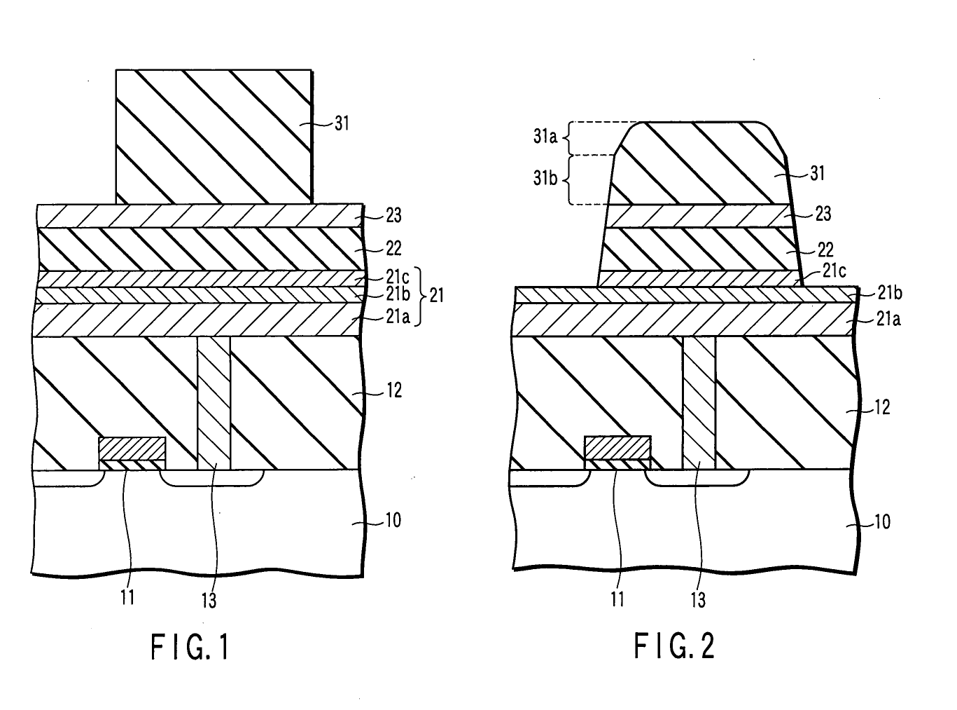

FIGS. 1 to 4 are schematic cross-sectional views illustrating steps of manufacturing a semiconductor device (ferroelectric memory) according to a first embodiment of the present invention.

First, as shown in FIG. 1, an isolation region (not shown) and a MIS transistor 11 are formed in a surface region of a silicon substrate (semiconductor substrate) 10. Next, an insulation region 12 including an interlayer insulating film is formed on the silicon substrate 10. Further, a plug 13 for electrically connecting the MIS transistor 11 and a capacitor described below is formed in the insulation region 12.

Next, an iridium (Ir) film 21a having a 120 nm thickness, an iridium oxide (IrO₂) film 21b having a 50 nm thickness and a platinum (Pt) film 21c having a 50 nm thickness are formed on the insulation region 12 by sputtering, as a bottom electrode film 21 of a capacitor. Then, a Pb(Zr_{X}Ti_{1-X})O₃ film (PZT film) 22 having a 140 nm thickness is formed on the platinum film 21c by sputtering, as a dielectric film of the capacitor. Further, a platinum (Pt) film 23 having a 70 nm thickness is formed on the PZT film 22 by sputtering, as a top electrode film of the capacitor.

Next, as a mask film, a silicon oxide film (SiO₂ film) 31 having a 1 μm thickness is formed on the platinum film 23 by plasma CVD (chemical vapor deposition). The mask film 31 is used as a hard mask when a pattern of the capacitor is formed. Thereafter, a photoresist pattern (not shown) is formed on the silicon oxide film 31 by photolithography. Further, with the photoresist pattern used as a mask, the silicon oxide film 31 is subjected to patterning by a magnetron RIE (reactive ion etching) equipment. After patterning of the silicon oxide film 31, the photoresist pattern is removed by ashing using oxygen gas plasma. Thereby, a mask formed of the silicon oxide film 31 is obtained.

Next, as shown in FIG. 2, with the silicon oxide film 31 used as a mask, the platinum film 23 is subjected to patterning by an induced combination plasma RIE equipment. A mixture gas of Cl₂ and Ar is used as etching gas. Flow rates of Cl₂ and Ar are 160 sccm and 40 sccm, respectively. The pressure in an RIE chamber is set to 2 Pa, the RF power fed to an induction combination coil thereof is set to 1 kW, and the RF power fed to a wafer susceptor is set to 200 W. Further, the temperature of the wafer susceptor is set to 350° C., and RIE is performed in the state where the semiconductor substrate 10 is heated. Platinum compounds generated in the RIE, such as platinum chloride, do not easily evaporate since they have a high saturated vapor pressure. Therefore, the platinum compounds adhered may impede good anisotropic etching. In this embodiment, RIE is performed in the state where the semiconductor substrate is heated at a temperature of about 300 to 400° C., and thus the anisotropic etching of the platinum film 23 can be performed satisfactorily.

After etching of the platinum film 23, with the silicon oxide film 31 used as a mask, the PZT film 22 and the platinum film 21c are subjected to patterning by the above induced combination plasma RIE equipment. A mixture gas of Cl₂, Ar and N₂ is used as etching gas. Flow rates of Cl₂, Ar and N₂ are 160 sccm, 40 sccm and 10 sccm, respectively. The other basic RIE conditions are the same as the above RIE conditions for the platinum film 23.

A cross section of a structure obtained thereby was observed by an SEM. As a result, the inclination angle (taper angle) of side surfaces of the platinum film 21c, PZT film 22, platinum film 23 and silicon oxide film 31 was about 85°. Since the silicon oxide film 31 is also etched by RIE, the film thickness of the silicon oxide film 31 was reduced. Further, the etching speed at a shoulder portion 31a of the silicon oxide film 31 is greater than the etching speed at a flat portion of the silicon oxide film 31. Therefore, the inclination angle of the shoulder portion 31a was smaller than the inclination angle (about 850 in this embodiment) of a non-shoulder portion 31b.

Next, as shown in FIG. 3, with the silicon oxide film 31 used as a mask, the iridium oxide film 21b and the iridium film 21a are subjected to patterning by the induced combination plasma RIE equipment. A mixture gas of Cl₂, Ar, N₂ and O₂ is used as etching gas. Flow rates of Cl₂, Ar, N₂ and O₂ are 160 sccm, 20 sccm, 30 sccm and 20 sccm, respectively. The pressure in the chamber in RIE is 4 Pa. The other basic RIE conditions are the same as the above RIE conditions for the platinum film 23.

A cross section of a structure obtained thereby was observed by an SEM. As a result, the inclination angle (taper angle) of side surfaces of the iridium film 21a, iridium oxide film 21b, the platinum film 21c, PZT film 22 and platinum film 23 was about 80°. The inclination angle (taper angle) of side surfaces of the silicon oxide film 31 was about 500. Further, the film thickness of the silicon oxide film 31 was further reduced.

The following is the reason why the inclination angle of the silicon oxide film 31 is smaller than the inclination angle of the other films. As already described with respect to the step shown in FIG. 2, the etching speed at the shoulder portion 31a of the silicon oxide film 31 is greater than the etching speed at the flat portion of the silicon oxide film 31. Therefore, the inclination angle of the shoulder portion 31a is smaller than the inclination angle of the non-shoulder portion 31b. Further, the silicon oxide film 31 is gradually thinned by RIE steps. As the silicon oxide film 31 is thinned, the shoulder portion moves downwards. Therefore, by optimizing the initial film thickness (1 μm in this embodiment) of the silicon oxide film 31 and the RIE conditions, it is possible to reduce the final film thickness of the silicon oxide film 31 to be almost equal to or less than the film thickness of the shoulder portion. As a result, a structure as shown in FIG. 3 is obtained, in which the inclination angle of the silicon oxide film 31 is smaller than that of the other films.

A capacitor structure is obtained by the above process. The structure includes the bottom electrode 21 formed of the iridium film 21a, iridium oxide film 21b and platinum film 21c, the dielectric film (ferroelectric film) 22 formed of the PZT film, and the top electrode 23 formed of the platinum film 23.

Next, as shown in FIG. 4, an interlayer insulating film (silicon oxide film) 41 covering the capacitor structure and the silicon oxide film (mask film) 31 is formed by plasma CVD using a mixture gas of silane (SiH₄) and oxygen. As a result, a good step coverage was obtained, and the capacitor was securely covered with the interlayer insulating film. Therefore, problems were avoided such as the problem of formation of voids on side surfaces of the capacitor and the problem of formation of voids between adjacent capacitors. Further, excellent capacitor property was obtained.

As described above, according to the first embodiment, the inclination of the side surfaces of the silicon oxide film (mask film) 31 is gentler than the inclination of the side surfaces of the bottom electrode 21, dielectric film 22 and top electrode 23 of the capacitor. Specifically, in a stack structure comprising the bottom electrode 21, dielectric film 22, top electrode 23 and mask film 31, the upper-layer portion of the stack structure has inclination gentler than that of the lower-layer portion thereof. Generally, the upper-layer portion has a larger influence on step coverage than that of the lower-layer portion. Therefore, according to the structure of this embodiment, a good step coverage is achieved. Further, in this embodiment, the lower-layer portion of the stack structure has a steep inclination (large inclination angle). This structure reduces the area occupied by a capacitor and distance between adjacent capacitors, and enables scale down and high integration of a semiconductor device (ferroelectric memory). Therefore, according to this embodiment, it is possible to achieve both scale down and good step coverage simultaneously, and obtain a semiconductor device having excellent property and reliability.

### Embodiment 2

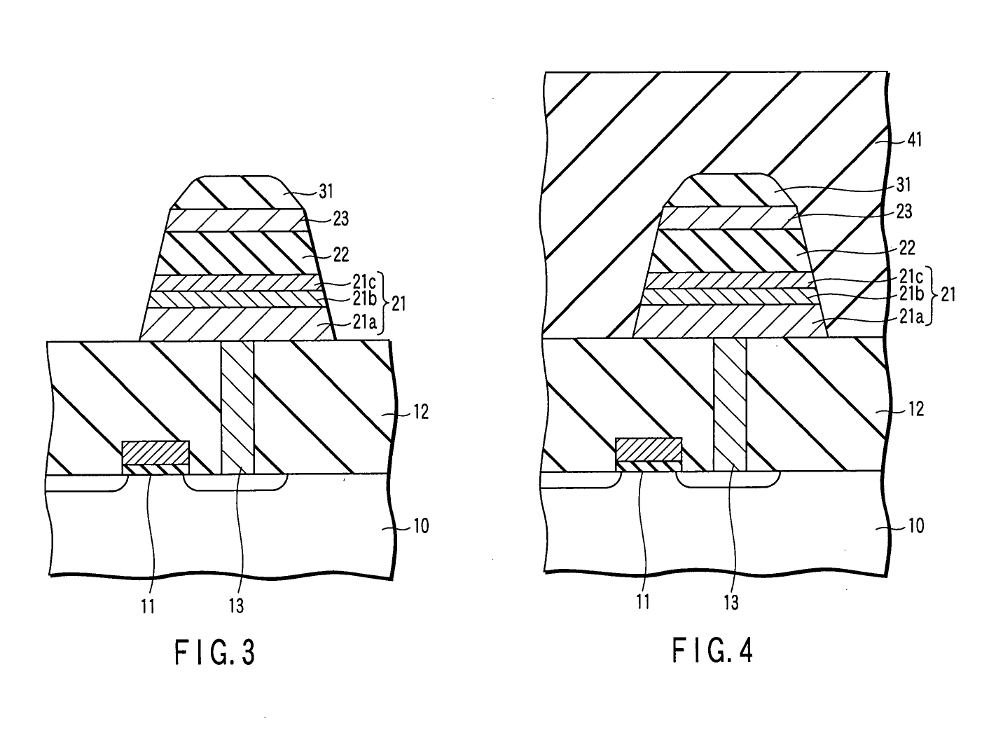

FIG. 5 is a schematic cross-sectional view illustrating a structure of a semiconductor device (ferroelectric memory) according to a second embodiment of the present invention. The basic structure thereof is the same as that of the first embodiment. Constituent elements corresponding to those shown in FIGS. 1 to 4 are denoted by the same reference numerals, and detailed explanation thereof is omitted. The basic manufacturing process thereof is also the same as that of the first embodiment, and detailed explanation thereof is omitted.

In the first embodiment, the initial film thickness of the silicon oxide film (mask film) 31 is 1 μm. In this second embodiment, the initial film thickness of a silicon oxide film 31 is 800 nm. Therefore, the final film thickness of the silicon oxide film 31 is thinner than that in the first embodiment, and the inclination of side surfaces of a platinum film 23 is also reduced as gentle as that of the silicon oxide film 31. As a result of actual observation by an SEM, the inclination angle (taper angle) of side surfaces of an iridium film 21a, iridium oxide film 21b, platinum film 21c and PZT film 22 was about 80°, and the inclination angle (taper angle) of side surfaces of the platinum film 23 and the silicon oxide film 31 was about 50°.

Also in the second embodiment, in a stack structure comprising the bottom electrode 21, dielectric film 22, top electrode 23 and mask film 31, the upper-layer portion of the stack structure has inclination gentler than that of the lower-layer portion, in the same manner as in the first embodiment. Therefore, like the first embodiment, the second embodiment can achieve both scale down and good step coverage simultaneously, and provide a semiconductor device having excellent property and reliability.

### Embodiment 3

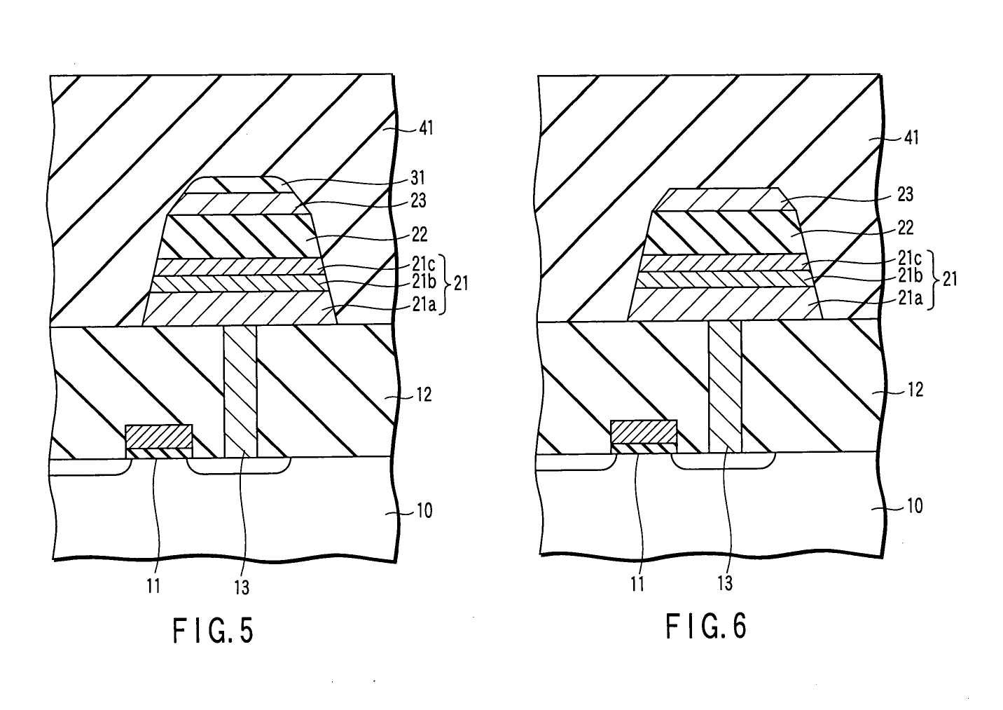

FIG. 6 is a schematic cross-sectional view illustrating a structure of a semiconductor device (ferroelectric memory) according to a third embodiment of the present invention. The basic structure thereof is the same as that of the first embodiment. Constituent elements corresponding to those shown in FIGS. 1 to 4 are denoted by the same reference numerals, and detailed explanation thereof is omitted. The basic manufacturing process thereof is also the same as that of the first embodiment, and detailed explanation thereof is omitted.

In the third embodiment, the initial film thickness of a silicon oxide film (mask film) 31 is further thinner than that of the second embodiment. As a result, the silicon oxide film 31 is completely etched and removed in the end of process. Further, in the same manner as in the second embodiment, the inclination angle (taper angle) of side surfaces of a platinum film 23 is smaller than the inclination angle (taper angle) of side surfaces of an iridium film 21a, iridium oxide film 21b, platinum film 21c and PZT film 22.

Also in the third embodiment, in a stack structure comprising the bottom electrode 21, dielectric film 22 and top electrode 23, the upper-layer portion of the stack structure has inclination gentler than that of the lower-layer portion, in the same manner as in the first and second embodiments. Therefore, like the first and second embodiments, the third embodiment can achieve both scale down and good step coverage simultaneously, and provide a semiconductor device having excellent property and reliability.

The first to third embodiments described above can be variously modified as follows.

As the mask film 31, it is possible to use a film including at least one film selected from silicon oxide film, silicon film, silicon nitride film, titanium film, titanium oxide film, titanium nitride film, aluminum film, aluminum oxide film, aluminum nitride film, carbon film, tungsten film, zirconium film, zirconium oxide film, yttrium film and yttrium oxide film.

As the dielectric film 22, an SrBi₂Ta₂O₉ film (SBT film) may be used as well as the PZT film. Generally, it is possible to use a ferroelectric film formed of metal oxide, as the dielectric film 22.

A film containing at least one element selected from platinum (Pt), iridium (Ir) and ruthenium (Ru) can be used in at least one of the bottom electrode 21 and the top electrode 23. Further, generally, a gas containing halogen element can be used for RIE for forming the capacitor structure. Compounds (in particular, halogen compounds) of platinum, iridium or ruthenium generally have a high saturated vapor pressure and thus may prevent good anisotropic etching. However, as described in the above embodiment, good anisotropic etching is possible by performing RIE at a temperature of about 300° C. or more.

The inclination angle of the upper-layer portion of the stack structure is preferably 45° to 70°, and the inclination angle of the lower-layer portion of the stack structure is preferably about 80° to 90°.

Further, in the above embodiments, all the bottom electrode 21, the dielectric film 22 and the top electrode 23 are subjected to patterning. However, the bottom electrode 21 is not always subjected to patterning, since there are cases where adjacent capacitors have a common bottom electrode.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a capacitor provided above the semiconductor substrate and including a bottom electrode, a dielectric film provided on the bottom electrode, and a top electrode provided on the dielectric film;
a mask film provided on the top electrode and used as a mask when a pattern of the capacitor is formed;
wherein an inclination of a side surface of the mask film is gentler than an inclination of a side surface of the top electrode and an inclination of a side surface of the dielectric film.

2. The semiconductor device according to claim 1, wherein
the inclination of the side surface of the top electrode is substantially equal to the inclination of the side surface of the dielectric film.

3. The semiconductor device according to claim 1, wherein
the inclination of the side surface of the mask film is gentler than an inclination of a side surface of the bottom electrode.

4. The semiconductor device according to claim 1, wherein
the dielectric film includes a ferroelectric film formed of a metal oxide.

5. The semiconductor device according to claim 1, wherein
the capacitor is covered with an interlayer insulating film.

6. A semiconductor device comprising:
a semiconductor substrate;
a capacitor provided above the semiconductor substrate and including a bottom electrode, a dielectric film provided on the bottom electrode, and a top electrode provided on the dielectric film;
a mask film provided on the top electrode and used as a mask when a pattern of the capacitor is formed;
wherein an inclination of a side surface of the mask film and an inclination of a side surface of the top electrode are gentler than an inclination of a side surface of the dielectric film.

7. The semiconductor device according to claim 6, wherein
the inclination of the side surface of the mask film is substantially equal to the inclination of the side surface of the top electrode.

8. The semiconductor device according to claim 6, wherein
the inclination of the side surface of the mask film and the inclination of the side surface of the top electrode are gentler than an inclination of a side surface of the bottom electrode.

9. The semiconductor device according to claim 6, wherein
the dielectric film includes a ferroelectric film formed of a metal oxide.

10. The semiconductor device according to claim 6, wherein
the capacitor is covered with an interlayer insulating film.

11. A semiconductor device comprising:
a semiconductor substrate; and
a capacitor provided above the semiconductor substrate and including a bottom electrode, a dielectric film provided on the bottom electrode, and a top electrode provided on the dielectric film;
wherein an inclination of a side surface of the top electrode is gentler than an inclination of a side surface of the dielectric film.

12. The semiconductor device according to claim 11, wherein
the inclination of the side surface of the top electrode is gentler than an inclination of a side surface of the bottom electrode.

13. The semiconductor device according to claim 11, wherein
the dielectric film includes a ferroelectric film formed of a metal oxide.

14. The semiconductor device according to claim 11, wherein
the capacitor is covered with an interlayer insulating film.
